(19) United States
(12) Patent Application Publication
(10) Pub. No.: US 2026/0211036 A1
(43) Pub. Date: Jul. 23, 2026

(54) DETECTION OF CONTACT RESISTANCE CHANGE IN CIRCUIT BREAKER

(71) Applicant: Schneider Electric USA, Inc., Boston, MA (US)

(72) Inventor: Bruno COLIN, Chicago, IL (US)

(21) Appl. No.: 19/035,277

(22) Filed: Jan. 23, 2025

(51) Int. Cl. G01R 31/327; H02B 1/24

(52) U.S. Cl. CPC G01R 31/327; H02B 1/24

(57) ABSTRACT

Thermal smart monitoring system for electrical distribution equipment, including a circuit breaker. A sensor provides temperature data associated with the circuit breaker. A diagnostics processor processes the sensor data and load data, which is representative of an electrical load in the electrical distribution equipment, as inputs to a trained machine learning model to determine a prediction whether an internal temperature response for the circuit breaker indicates an increase in contact resistance corresponding to a degradation of the condition of the internal contacts.

### BACKGROUND

Circuit breakers protect electrical circuits from damage caused by overcurrent, short circuits, or overload. They interrupt the flow of current when a fault occurs and restore it after the fault has been cleared. When faults occur, circuit breakers can protect people from electrical shocks and also help prevent equipment damage, fire hazards, and power outages caused by the faults.

Contact resistance is the resistance to current flow between two contacts that are touching each other (i.e., in the closed condition), such as the contacts of circuit breakers and other electrical switching devices (e.g., contactors, relays, switches, connectors, etc.). Contact resistance is often attributed to eroded contact surfaces and contaminated or corroded contacts. The contact tips in a breaker degrade over time due to prolonged storage, a high number of operations, initial manufacturing non-conformity, repeated electrical arcing, debris, etc. The build-up of resistance significantly decreases the contacts' ability to carry current and is detrimental to breaker performance.

There are two common checks for contact resistance in a circuit breaker: a visual inspection and a contact resistance measurement. The visual inspection involves examining the contacts of the circuit breaker for any pitting due to arcing, worn or deformed contacts, debris, and any other build-up. The contact resistance measurement involves injecting a fixed current through the contacts and measuring the voltage drop across them. Because the contacts are typically located deep inside the breaker and are difficult to access, conventional tests for contact resistance are time-consuming and labor intensive. Conventional tests require physical and visual access to the contacts inside the breaker, which requires an installation shutdown because the inspection must be performed without power. In addition, relatively minor contact resistance cannot by visually detected but the resulting drift in the way in which a breaker acts may have significant impact. Contact measurement methods are difficult to deploy and lack accuracy if not expertly realized, which can lead to non-detection or false detection of drifts.

### SUMMARY

Aspects of the present disclosure provide reliable and continuous monitoring of contact resistance while avoiding intrusive maintenance. A machine learned model determines a thermal normality space and monitors the drift of a circuit breaker to predict contact degradation. By modeling temperature as a function of ambient conditions and load, the machine learned model predicts what would be normal expected temperature associated with circuit breakers based on the measured ambient conditions and load. Monitoring the drift from normal allows detection of abnormalities in a faster and more accurate way than traditional threshold-based or visual monitoring for detecting undesired contact resistance.

In an aspect, a method of thermal smart monitoring of electrical distribution equipment includes receiving sensor data from one or more sensors and receiving load data representative of an electrical load flowing through the electrical distribution equipment. The electrical distribution equipment includes at least one circuit breaker and the sensor data comprises temperature data associated with the circuit breaker.

The circuit breaker comprises one or more contacts that are configured to switch between a closed state and an open state. The method further comprises processing the sensor data and the load data as inputs to a trained machine learning model to model temperature of the circuit breaker and determine contact resistance between the contacts of the circuit breaker in the closed state based on the modeled temperature.

In another aspect, a smart monitoring system for electrical distribution equipment includes one or more sensors configured to provide sensor data and a diagnostics processor receiving and responsive to the sensor data and to load data representative of an electrical load flowing through the electrical distribution equipment. The electrical distribution equipment includes at least one circuit breaker and the sensor data comprises temperature data associated with the circuit breaker. The circuit breaker comprises a plurality of contacts that are configured to switch between a closed state and an open state. The system further comprises a memory coupled to the diagnostics processor. The memory stores processor-executable instructions that, when executed, configure the diagnostics processor for processing the sensor data and the load data as inputs to a trained machine learning model to model temperature of the circuit breaker and determine contact resistance between the contacts of the circuit breaker in the closed state based on the modeled temperature.

In yet another aspect, an electrical distribution system comprises one or more electric load carrying components configured for supplying power to an electrical load and at least one circuit breaker electrically connected to the electric load carrying components. The circuit breaker comprises a plurality of contacts that are configured to switch between a closed state and an open state. One or more sensors are configured to provide sensor data, namely, temperature data associated with the circuit breaker. The system also includes a diagnostics processor receiving and responsive to the sensor data and to load data representative of the electrical load. A memory coupled to the diagnostics processor stores processor-executable instructions that, when executed, configure the diagnostics processor for processing the sensor data and the load data as inputs to a trained machine learning model to model temperature of the circuit breaker and determine contact resistance between the contacts of the circuit breaker in the closed state based on the modeled temperature.

Other objects and features of the present invention will be in part apparent and in part pointed out herein.

### BRIEF DESCRIPTION OF THE DRAWINGS

FIG. 1 illustrates a thermal smart monitoring system according to an embodiment.

FIGS. 2A to 2D illustrate aspects of an electrical protection device according to an embodiment.

FIG. 3 is a block diagram illustrating networked sensors according to an embodiment.

FIG. 4 illustrates an example network for the thermal smart monitoring system of FIG. 1 according to an embodiment.

FIGS. 5A and 5B illustrate example thermal response curves for predicting an alarm condition according to an embodiment.

FIG. 6 is a flow diagram of an example process for anticipating a possible outage based on a machine learned model according to an embodiment.

FIGS. 7A and 7B illustrate example thermal response curves for determining normality drift according to an embodiment.

FIG. 8 is a flow diagram of an example process for measuring drift from a normality space based on a machine learned model according to an embodiment.

FIG. 9 is a flow diagram of an example process for predicting a change in contact resistance in a circuit breaker according to an embodiment.

FIGS. 10 and 11 illustrate example actual and modeled temperature curves according to an embodiment.

Corresponding reference characters indicate corresponding parts throughout the drawings.

### DETAILED DESCRIPTION

The features and other details of the concepts, systems, and techniques sought to be protected herein will now be more particularly described. It will be understood that any specific embodiments described herein are shown by way of illustration and not as limitations of the disclosure and the concepts described herein. Features of the subject matter described herein can be employed in various embodiments without departing from the scope of the concepts sought to be protected.

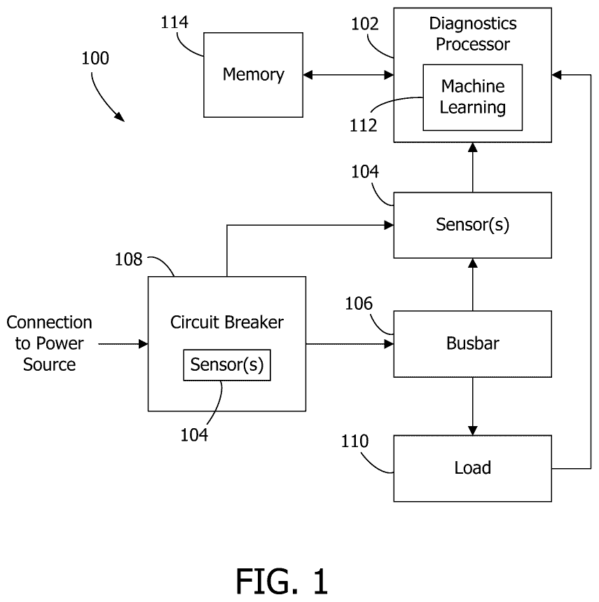

Referring to FIG. 1, a system 100 combines circuit breaker electronic current sensor capability with internal temperature sensing to provide specific diagnostics of thermal anomalies, aging degradation, and the like for electrical distribution equipment such as circuit breakers. A diagnostics processor 102, located in the installation or accessed through a cloud connection, receives temperature sensor data from a plurality of sensors 104. According to one or more embodiments, the diagnostics processor 102 may be embodied by a microprocessor or other computing system as described below.

Aspects of the present disclosure provide reliable and continuous monitoring of contact resistance in electrical distribution equipment. In an embodiment, one or more of the sensors 104 are associated with electric load carrying components (e.g., busbars and/or busways). In the illustrated embodiment, a busbar 106 is an instance of electrical distribution equipment. In another embodiment, one or more of the sensors 104 are associated with a circuit breaker 108 electrically connected to the busbar 106. The diagnostics processor 102 also receives load data describing a current electrical load 110 for the electrical distribution equipment embodied by the system 100. In turn, diagnostics processor 102 processes the temperature sensor data and the load data as inputs to a trained machine learning model 112 to determine a prediction of the temperature of circuit breaker 108. It is to be understood that the system 100 may include any number of sensors 104, busbars 106, and/or circuit breakers 108 within the scope of the present disclosure.

The diagnostics processor 102 of system 100 receives temperature sensor data from the plurality of sensors 104. In accordance with this embodiment, diagnostics processor 102 also receives load data describing a current electrical load 110 for the electrical distribution equipment embodied by the system 100. During operation of the current electrical load 110, diagnostics processor 102 receives subsequent temperature sensor data from sensors 104. A memory 114 coupled to diagnostics processor 102 stores processor-executable instructions that, when executed, configure diagnostics processor 102 for processing the sensor data and the load data as inputs to the trained machine learning model 112 to model temperature of circuit breaker 108. In an embodiment, diagnostics processor 102 processes the temperature sensor data, the load data, and the subsequent temperature sensor data to determine whether the subsequent temperature sensor data significantly deviates from predicted temperature sensor data expected to be caused by the current electrical load.

The diagnostics processor 102 then generates an electronic or visual notification based on the determination. In an embodiment, the notification comprises, but is not limited to, a signal triggering a visible light indicator, an audible alarm, or other alert, such as a flag or banner activating in a user Interface application, an electronic mail being sent to predetermined user, a change of color on any digital screen equipping the circuit breaker or the switchgear containing the circuit breaker.

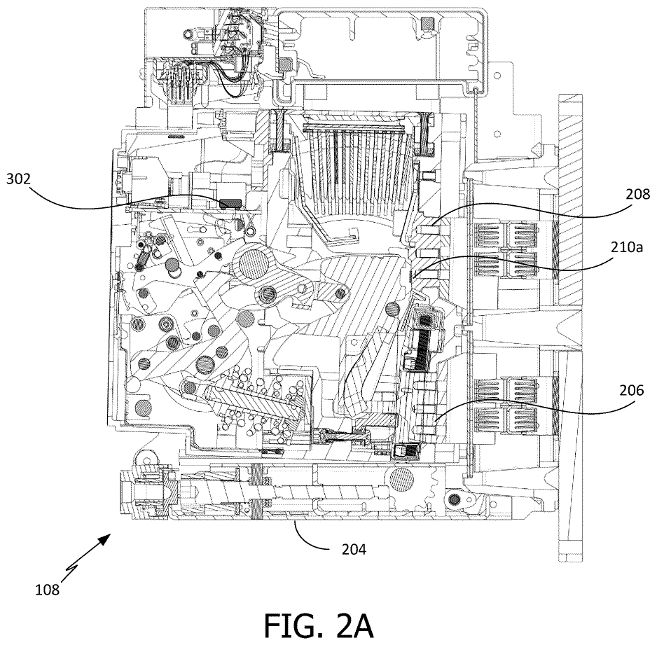

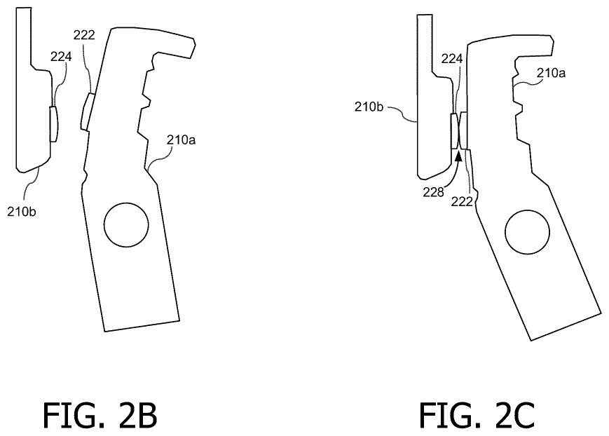

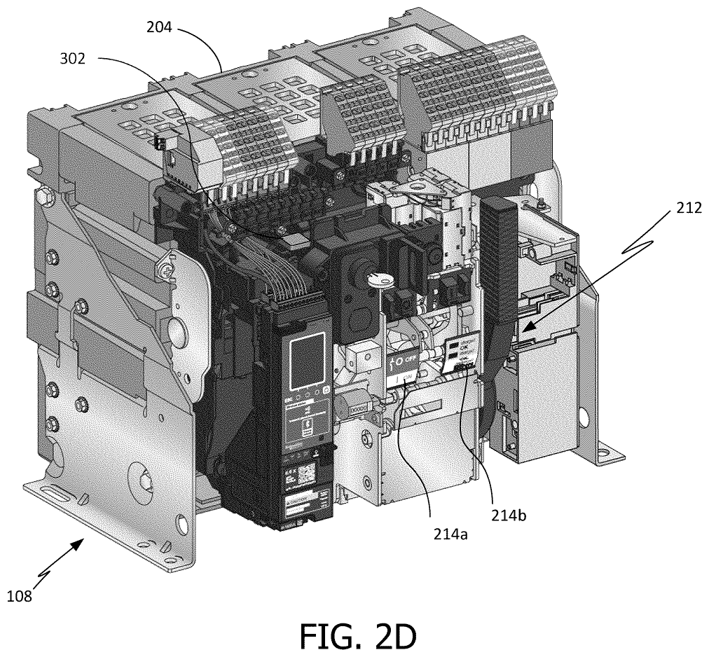

FIGS. 2A to 2D represent aspects of an electrical protection device that can be used to protect an electrical system against abnormal conditions, such as overvoltages, short circuits, and/or overcurrents. In one or more embodiments, the electrical protection device comprises circuit breaker 108. The circuit breaker 108 may be a high-power air circuit breaker, for example, capable of carrying current at a between a few hundred and a few thousand amps (e.g., between 500 A and 7500 A) in a normally-closed state.

The circuit breaker 108 here comprises a casing 204 inside of which are housed at least some of its components (see FIG. 2A having a front cover of the casing 204 removed). It will be understood that, in this example, the components of the electrical protection system are housed in the same casing 204. However, in certain variants, certain components could be housed in different casings. Everything described here with reference to the circuit breaker 108 is therefore generalizable to an electrical protection system that can be dissociated from the casing 204.

The circuit breaker 108 also comprises connection terminals 206 and 208, separable electrical contacts 210a, 210b (see FIGS. 2B and 2C) connected between the connection terminals 206 and 208 and a switching mechanism 212 comprising open and close buttons 214a, 214b (see FIG. 2D having a front cover of the casing 204 removed). For example, the contacts may be formed by associating a fixed electrical contact 210b and a mobile electrical contact 210a that is movable with respect to the fixed contact, the switching mechanism 212 being coupled to the mobile electrical contact 210a. In practice, each electrical contact 210a, 210b may comprise a plurality of electrical contact fingers, although other implementations are possible as variants.

The separable electrical contacts 210a, 210b are movable between an open state as shown in FIG. 2B and a closed state as shown in FIG. 2C. In the open state, the contact 210a is separated from contact 210b by a volume of ambient air acting as an electrical insulator, i.e., an air gap, thus preventing an electrical current from flowing. FIGS. 2B and 2C further illustrate a mobile contact tip 222 on the mobile contact 210a and a fixed contact tip 224 on the fixed contact 210b. The contact resistance when contact tips 222, 224 are closed is indicated at 228.

Aspects of the present disclosure relate to temperature sensor 104 placed internally to circuit breaker 108, in conjunction with the electric load following through circuit breaker 108 and ambient temperature. As described below, a temperature model of circuit breaker 108 is established through machine learning, which permits predicting the temperature internal to the breaker based on the load and environmental data (e.g., the ambient conditions of the electrical distribution equipment). The progressive degradation over time of the contact tips 222, 224 triggers a progressive increase of the internal temperature of circuit breaker 108 under equivalent conditions. By comparing the predicted value and the current value of the temperature, the additional heat brought by tip degradation can be detected and notified to the circuit breaker user.

In an embodiment, circuit breaker 108 comprises multiple pairs of connection terminals 206, 208: a first input terminal 206 is connected to a first output terminal 208 by way of a first connection line, and a second input terminal 206 connected to a second output terminal 208 by way of a second connection line. In many embodiments, the switching mechanism 212 is configured to move the electrical contacts 210a, 210b to an open state in response to a switching command. The switching command may be sent by a tripping device or result from an action of a user on the control lever 214a, 214b. For example, the electrical faults may be current surges or short-circuits, but also other electrical faults such as a differential current or presence of a series (or differential) arc in the line to be protected, or even also voltage surges or voltage sags. When tripped (i.e., following detection of an electrical fault requiring immediate interruption of electrical current), switching mechanism 212 switches circuit breaker 108.

Aspects of the present disclosure provide reliable and continuous monitoring of contact resistance while avoiding intrusive maintenance. A machine learned model determines a thermal normality space and monitors the drift of circuit breaker temperature to predict contact degradation. By modeling circuit breaker internal temperature as a function of load and ambient temperature of the electrical distribution equipment (e.g., ambient temperature external to circuit breaker 108), the machine learned model predicts what would be normal expected temperature associated with circuit breakers based on the measured ambient temperature and load. Monitoring the drift from normal, by comparing the predicted value to the measured value, allows detection of abnormalities in a faster and more accurate way than traditional threshold-based or visual monitoring for detecting undesired contact resistance increase.

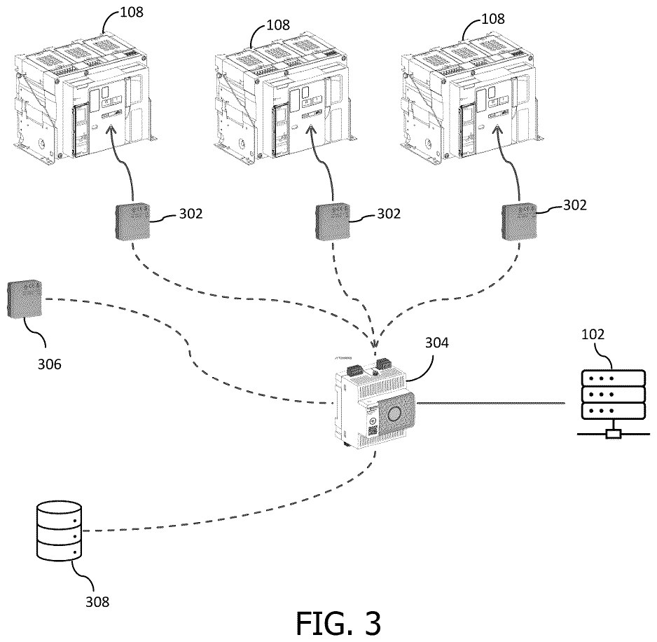

FIG. 3 illustrates a plurality of sensors 104. In the illustrated embodiment, sensors 104 comprise a plurality of temperature sensors 302 connected wirelessly to a gateway 304. Alternatively, a wired connection can be used. In addition, an equivalent sensor 306 collects ambient temperature readings. It is to be understood that the plurality of sensors 104, including the sensors 302, 306, may be installed in connection with one or more circuit breakers 108 at various locations, such as internally or on one the external surfaces of circuit breakers 108. The electric current flowing through circuit breaker 108 is collected through existing solutions, stored in a database 308, and provided through the same gateway 304 for processing by diagnostics processor 102 through a wired, wireless, or cloud connection. In an embodiment, the gateway information is stored or processed live.

In an embodiment, temperature sensor 302 is located internally to circuit breaker 108 and, in conjunction with the electric load flowing through the circuit breaker and ambient temperature probe 306, diagnostics processor 102 establishes a temperature model of circuit breaker 108 through machine learning and, in turn, predicts the temperature internal to breaker 108 based on the load and the ambient temperature. The progressive degradation over time of the contact tips 222, 224 triggers a progressive increase of the internal temperature of circuit breaker 108. By comparing the predicted value and the current value of the temperature, the additional heat brought by tip degradation can be detected and notified to the circuit breaker user.

The use of machine learning to create a model of the internal temperature of circuit breaker 108 based on load is an improvement on existing monitoring solutions that focus on sensors located at the circuit breaker external connections. In this instance, external temperature sensors are incapable of accurately detecting internal temperature variations to the breaker. Moreover, aspects of the present disclosure use the normality space drift of circuit breaker 108, as a tool to anticipate physical degradation of the circuit breaker 108.

According to one or more embodiments, an increase in contact resistance at the circuit breaker contacts 222, 224 is progressive and typically only generates a few degrees of temperature increase. Without an accurate temperature behavior modeling of the circuit breaker 108, the heat increase is not noticeable and therefore incapable of providing a measure of contact resistance. Using machine learning capabilities, predictions can be made relative accuracy (e.g., within 1° C.), allowing to detect minor gaps such as the one described here.

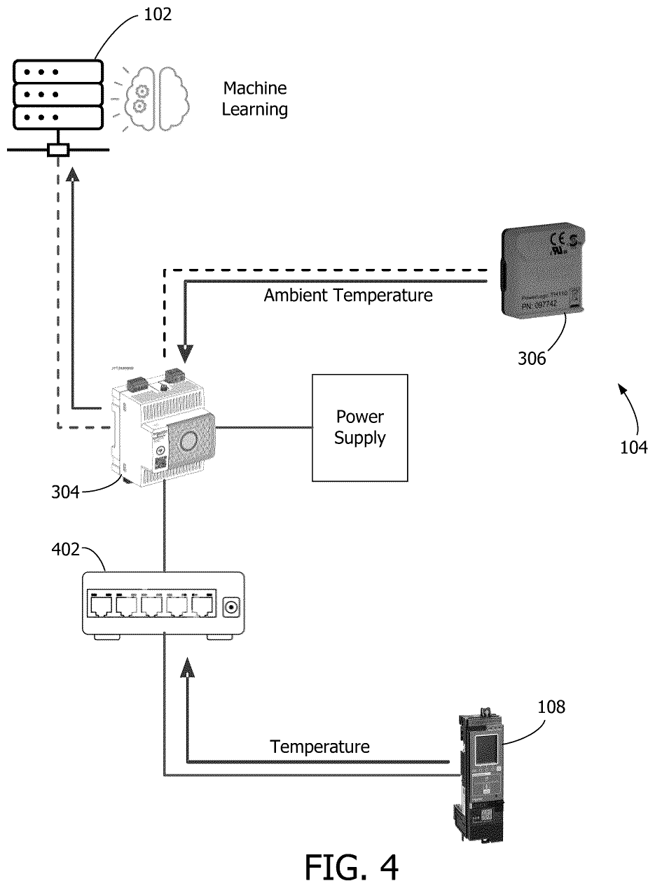

FIG. 4 illustrates further aspects of the present disclosure. In FIG. 4, current sensors associated with circuit breaker 108 provide load data to diagnostics processor 102 via an Ethernet connection point 402, for example, and the gateway 304. The sensors 302 provide temperature data associated with circuit breaker 108 and sensor 306 provides ambient temperature data. Alternatively, diagnostics processor 102 receives the sensor data via gateway 304 similar to the load data. The diagnostics processor 102 uses the current data provided by circuit breaker 108 and the temperature data provided by the external sensors 104 to access key factors of application through machine learning, including monitoring for potential problems and aging of components.

Feeding the data captured by this combination of sensors permits the normality space of the circuit breaker 108 to be expressed as model temperature as a function of ambient conditions and load. In other words, the machine learned model executed by diagnostics processor 102 predicts what would be normal, expected temperature associated with circuit breakers 108 based on the measured ambient conditions and load. Monitoring the drift of this normality space allows detection of abnormalities in a faster and more accurate way than traditional threshold-based monitoring.

At least two direct use cases can be made, namely, A) using the model (e.g., operating point) created to predict the operation of the breaker for different load levels, and anticipating a possible outage due to a brutal stop if current conditions are maintained, thus giving anticipated warning to customer; and B) using the model (e.g., operating point) created to measure a drift away of this operating point (measured temperature drifting away from model predicted temperature).

### Use Case A: Prediction of Operating Conditions

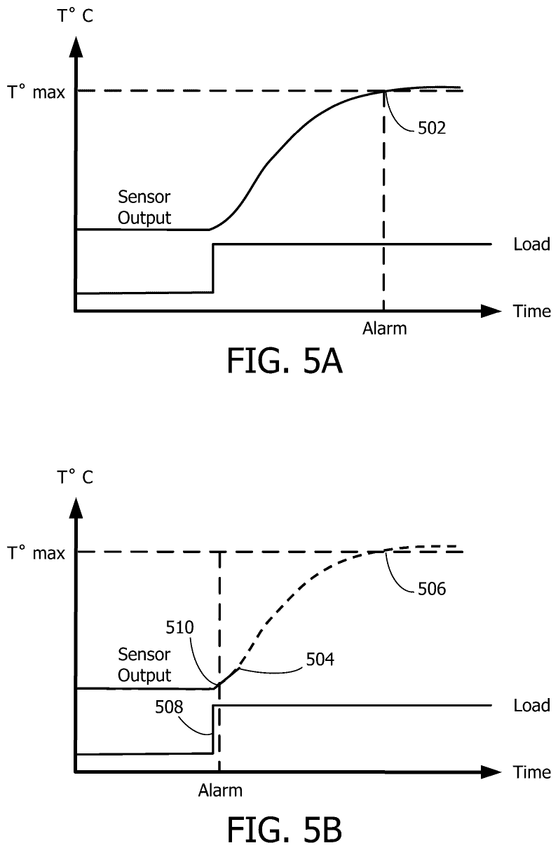

Referring to FIG. 5A, an example of conventional thermal threshold alarming is shown. When the monitored temperature exceeds a threshold Tmax indicating detection of excessive temperature, an alarm is generated at 502.

FIG. 5B illustrates an example of predictive alarm management in accordance with one or more embodiments. In this example, including ambient temperature in one or more embodiments, diagnostics processor 102 learns the relationship between load and temperature by monitoring temperature measurements as a function of load and then modeling the temperature, beginning at 504, to predict when the temperature will exceed Tmax at 506. Using the machine learned model, diagnostics processor 102 is able to predict the temperature response to a new load at 508 and generate an alarm at 510 anticipating the excessive temperature condition. In this manner, aspects of the present disclosure permit a much longer window of time for evaluating and possibly resolving the problem before it becomes critical.

In addition, the machine learned model permits preventive alarm management. The model learns load patterns (e.g., evaluation of days/times/events triggering high load, such as every Monday morning or during generator test runs) and can generate an alarm before a load increase. In this manner, the model anticipates condition in response to load changes and provides alerts before a condition becomes problematic.

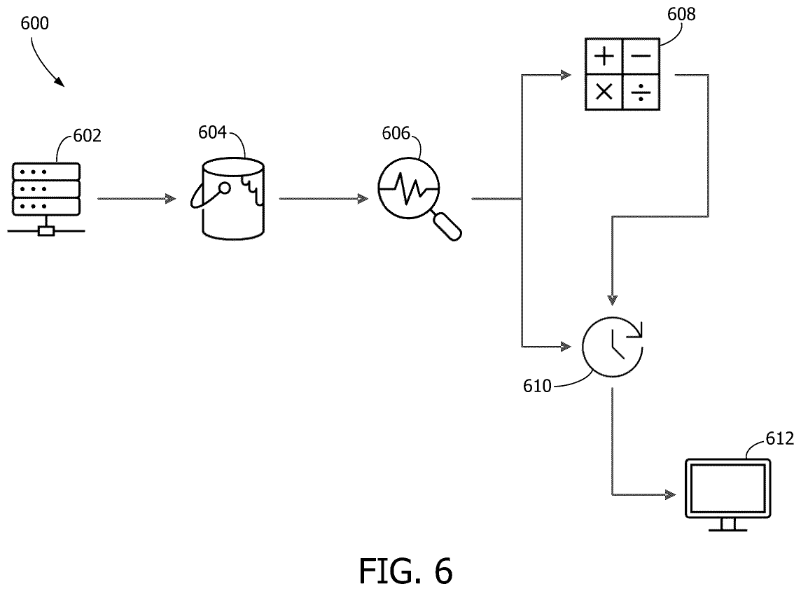

FIG. 6 illustrates an example process 600 for predicting a future state in conjunction with circuit breaker contact resistance to illustrate further aspects of Use Case A, described above. Beginning at 602, diagnostics processor 102 receives data from sensors 104 for collecting a data set including, for example, time, electric current load, ambient temperature, and breaker temperature. To improve data processing and speed, the collected data is consolidated at regular intervals (e.g., 1 hour), as indicated by a data bucket at 604. The diagnostics processor 102 executes a machine learning regression algorithm at 606 to establish a specific model for every monitored circuit breaker 108. At 608, the parameters of the machine learned model are stored as an initial normality space and, at 610, diagnostics processor 102 establishes a prediction of temperature over the next 24 hours, for example, based on the model and live data. The diagnostics processor 102 compares the live temperature data to the prediction at 612. If the predictions indicate values exceeding pre-established thresholds, an alarm is generated.

### Use Case B: Detection of Behavior Drift

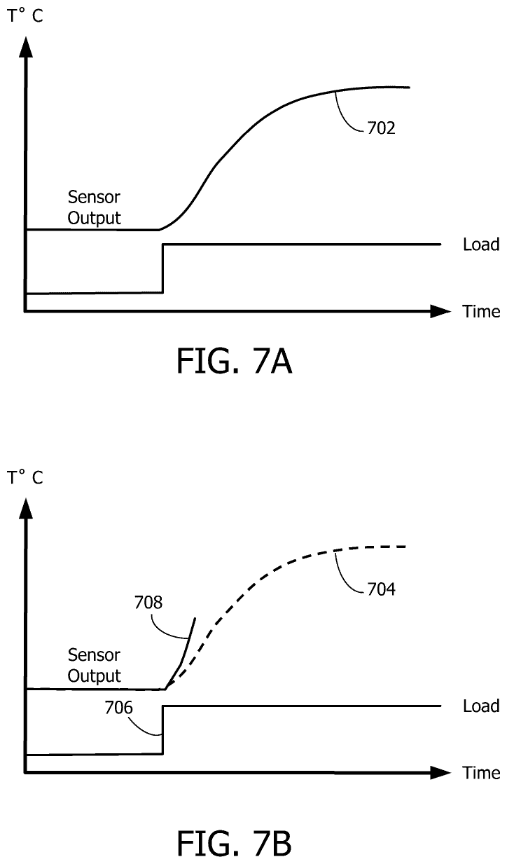

Referring to FIG. 7A, an example of conventional thermal behavior of application is shown at 702 (similar to FIG. 5A).

FIG. 7B illustrates an example of predictive alarm management in accordance with one or more embodiments. In this example, including ambient temperature in one or more embodiments, diagnostics processor 102 learns the relationship between load and temperature by monitoring temperature measurements as a function of load, and identifies when the measured (thermal) behavior differs from the expected or usual pattern. Using the machine learned model, diagnostics processor 102 is able to predict the temperature response to a new load at 704. If in response to a new load at 706, the measured thermal behavior deviates significantly from the prediction, as indicated at 708, an alarm is generated based on this change of behavior and a maintenance request may be put in. In this manner, the machine learning of diagnostics processor 102 observes the relationship between load and temperature and compares the observed temperature to the predicted temperature to identify abnormal conditions. In an embodiment, value-based comparison is made (e.g., 32° C. vs. 30° C.). In another embodiment, aspects of the present disclosure may provide improved accuracy with a drift pattern analysis by quickly isolating spikes at current level changes from the average value of the drift.

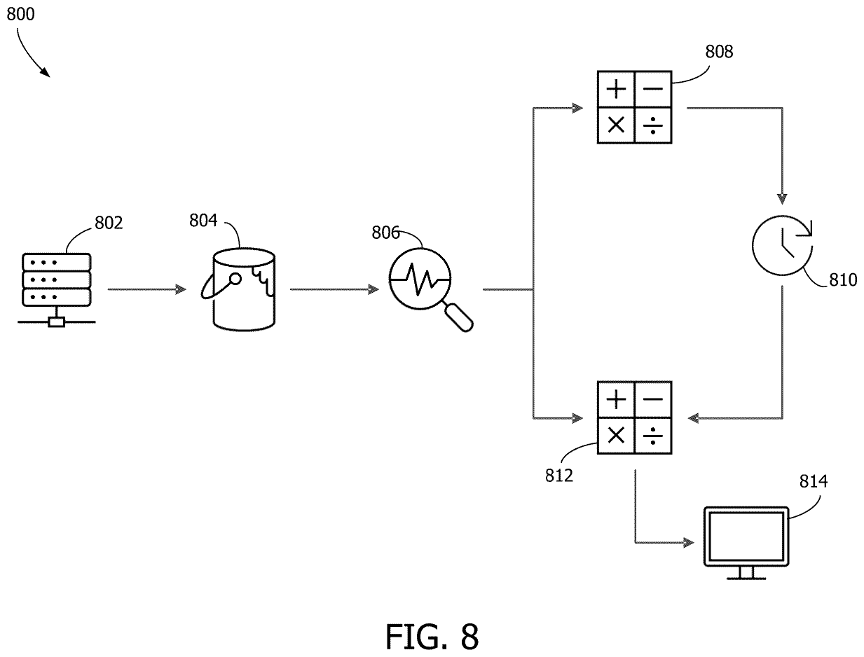

FIG. 8 illustrates an example process 800 for determining normality space drift in conjunction with circuit breaker contact resistance to illustrate further aspects of Use Case B, described above. Beginning at 802, diagnostics processor 102 receives data from sensors 104 for collecting a data set including, for example, time, electric current load, ambient temp, and breaker temperature. To improve data processing and speed, the collected data is consolidated at regular intervals (e.g., 1 hour), as indicated by a data bucket at 804. The diagnostics processor 102 executes a machine learning regression algorithm at 806 to establish a specific model for every monitored junction. At 808, the parameters of the machine learned model are stored as an initial normality space and, at 810, diagnostics processor 102 establishes a prediction of temperature and vibration based on live load, time, and ambient conditions data. At 812, the process 800 operates on the model and live data. The diagnostics processor 102 compares the live temperature and vibration data to the prediction at 814. If the comparison reveals drift exceeding pre-established thresholds, an alarm is generated.

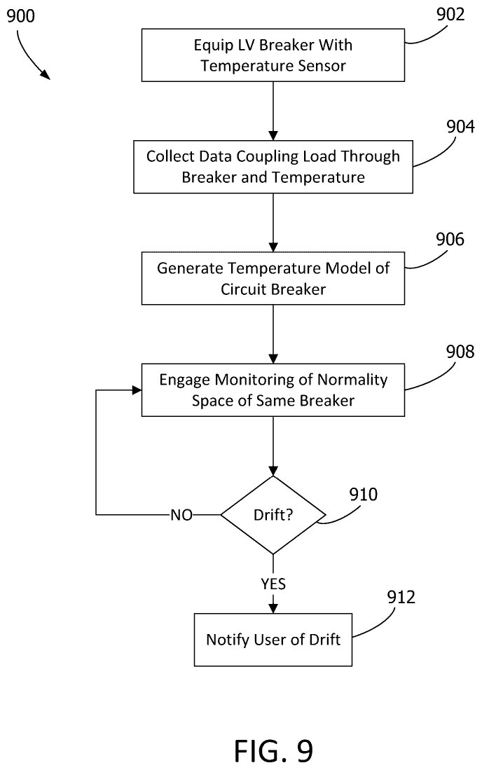

FIG. 9 illustrates an example process 900 for identifying drift relative to a normal circuit breaker temperature response to determine a change in contact resistance.

Beginning at 902, circuit breaker 108 is equipped with an internal temperature sensor 302. The diagnostics processor 102 at 904 collects data representative of the electrical load through breaker 108 coupled with the temperature data acquired from sensor 302. At 906, diagnostics processor 102 executes a machine learned model for generating a temperature model of circuit breaker 108. In an embodiment, the machine learned model has been trained based on many hours of data using different load levels.

Proceeding to 908, the process 900 engages monitoring of a normality space for the same breaker 108. In other words, diagnostics processor 102 compares the temperature model to the expected temperature response of a circuit breaker having no increase in contact resistance. If the diagnostics processor 102 determines the model is drifting from the normality space at 910, process 900 proceeds to 912 for notifying the user.

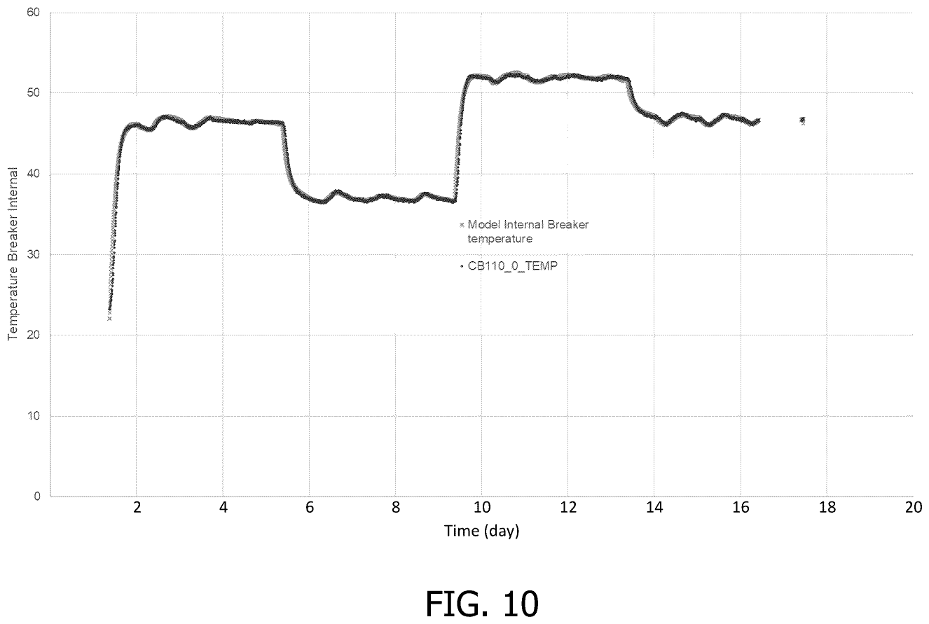

Referring now to FIG. 10, a graph is shown that compares actual temperature sensor readings acquired from sensor 302 for circuit breaker 108 overlaid by a temperature model of the temperature response generated by a machine learned model. In an embodiment, the machine learned model has been trained based on many hours of data (e.g., 192 hours) using different load levels. Features of the model include the electrical load through circuit breaker 108 and the ambient temperature measured external to a switchgear (e.g., acquired by sensor 306). Ambient temperature affects the temperature within the breaker 108 and, thus, is factored into the model. The model is based on temperature and load data at different ambient temperatures for good, non-degraded contacts 222, 224 and the internal temperature of circuit breaker 108. As shown in FIG. 10, the modeled temperature response and the acquired temperature readings for training the model match.

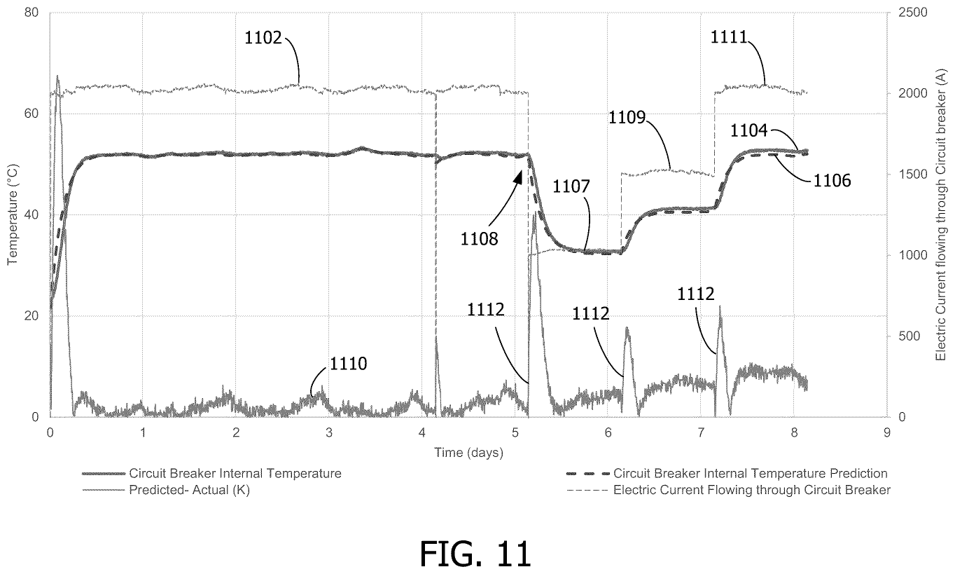

In the example of FIG. 11, a load curve 1102, an internal temperature measure curve 1104 for breaker 108, and a prediction model temperature curve 1106 are shown. An arrow 1108 indicates the occurrence of a defect. For test purposes, a defect is created by adding resistive tape on the tips of the contacts 222, 224. For example, if the breaker 108 has 10 fingers, placing tape on three fingers can be used to simulate a defect. Electric current is adjusted several times (see, for example, 1107, 1109, 1111) to illustrate one or more embodiments under different conditions. At 1110, a gap between the predicted value and the measured value is shown. As the internal temperature of breaker 108 drifts from the prediction as a result of the simulated contact resistance, the gap as indicated at 1110 increases. For instance, this reading increases as shown at 1112 following the defect created at 1108. The average of the predicted temperature actual temperature with no defect is 0.191° K. in the illustrated example whereas this difference is 0.616° K. resulting from the defect.

Embodiments of the present disclosure may comprise a special purpose computer including a variety of computer hardware, as described in greater detail herein.

For purposes of illustration, programs and other executable program components may be shown as discrete blocks. It is recognized, however, that such programs and components reside at various times in different storage components of a computing device, and are executed by a data processor(s) of the device.

Although described in connection with an example computing system environment, embodiments of the aspects of the invention are operational with other special purpose computing system environments or configurations. The computing system environment is not intended to suggest any limitation as to the scope of use or functionality of any aspect of the invention. Moreover, the computing system environment should not be interpreted as having any dependency or requirement relating to any one or combination of components illustrated in the example operating environment. Examples of computing systems, environments, and/or configurations that may be suitable for use with aspects of the invention include, but are not limited to, personal computers, server computers, hand-held or laptop devices, multiprocessor systems, microprocessor-based systems, set top boxes, programmable consumer electronics, mobile telephones, network PCs, minicomputers, mainframe computers, distributed computing environments that include any of the above systems or devices, and the like.

Embodiments of the aspects of the present disclosure may be described in the general context of data and/or processor-executable instructions, such as program modules, stored in memory, i.e., one or more tangible, non-transitory storage media, and executed by one or more processors or other devices. Generally, program modules include, but are not limited to, routines, programs, objects, components, and data structures that perform particular tasks or implement particular abstract data types. Aspects of the present disclosure may also be practiced in distributed computing environments where tasks are performed by remote processing devices that are linked through a communications network. In a distributed computing environment, program modules may be located in both local and remote storage media including memory storage devices.

In operation, processors, computers and/or servers may execute the processor-executable instructions (e.g., software, firmware, and/or hardware) such as those illustrated herein to implement aspects of the invention.

Embodiments may be implemented with processor-executable instructions. The processor-executable instructions may be organized into one or more processor-executable components or modules on a tangible processor readable storage medium. Also, embodiments may be implemented with any number and organization of such components or modules. For example, aspects of the present disclosure are not limited to the specific processor-executable instructions or the specific components or modules illustrated in the figures and described herein. Other embodiments may include different processor-executable instructions or components having more or less functionality than illustrated and described herein.

The order of execution or performance of the operations in accordance with aspects of the present disclosure illustrated and described herein is not essential, unless otherwise specified. That is, the operations may be performed in any order, unless otherwise specified, and embodiments may include additional or fewer operations than those disclosed herein. For example, it is contemplated that executing or performing a particular operation before, contemporaneously with, or after another operation is within the scope of the invention.

When introducing elements of the invention or embodiments thereof, the articles “a,” “an,” “the,” and “said” are intended to mean that there are one or more of the elements. The terms “comprising,” “including,” and “having” are intended to be inclusive and mean that there may be additional elements other than the listed elements.

Not all of the depicted components illustrated or described may be required. In addition, some implementations and embodiments may include additional components. Variations in the arrangement and type of the components may be made without departing from the spirit or scope of the claims as set forth herein. Additional, different or fewer components may be provided and components may be combined. Alternatively, or in addition, a component may be implemented by several components.

The above description illustrates embodiments by way of example and not by way of limitation. This description enables one skilled in the art to make and use aspects of the invention, and describes several embodiments, adaptations, variations, alternatives and uses of the aspects of the invention, including what is presently believed to be the best mode of carrying out the aspects of the invention. Additionally, it is to be understood that the aspects of the invention are not limited in its application to the details of construction and the arrangement of components set forth in the following description or illustrated in the drawings. The aspects of the invention are capable of other embodiments and of being practiced or carried out in various ways. Also, it will be understood that the phraseology and terminology used herein is for the purpose of description and should not be regarded as limiting.

It will be apparent that modifications and variations are possible without departing from the scope of the invention defined in the appended claims. As various changes could be made in the above constructions and methods without departing from the scope of the invention, it is intended that all matter contained in the above description and shown in the accompanying drawings shall be interpreted as illustrative and not in a limiting sense.

In view of the above, it will be seen that several advantages of the aspects of the invention are achieved and other advantageous results attained.

The Abstract and Summary are provided to help the reader quickly ascertain the nature of the technical disclosure. They are submitted with the understanding that they will not be used to interpret or limit the scope or meaning of the claims. The Summary is provided to introduce a selection of concepts in simplified form that are further described in the Detailed Description. The Summary is not intended to identify key features or essential features of the claimed subject matter, nor is it intended to be used as an aid in determining the claimed subject matter.

1. A method of thermal smart monitoring of electrical distribution equipment, the electrical distribution equipment including at least one circuit breaker, the circuit breaker comprising a plurality of contacts, the contacts configured to switch between a closed state and an open state, the method comprising:
receiving sensor data from one or more sensors, wherein the sensor data comprises temperature data associated with the circuit breaker;
receiving load data representative of an electrical load flowing through the electrical distribution equipment; and
processing the sensor data and the load data as inputs to a trained machine learning model to model temperature of the circuit breaker and determine contact resistance between the contacts of the circuit breaker in the closed state based on the modeled temperature.

2. (canceled)

3. The method of claim 1, wherein the sensor data further comprises environmental data associated with ambient conditions of the electrical distribution equipment and wherein processing the sensor data and the load data comprises modeling temperature of the circuit breaker as a function of the ambient conditions and the electrical load.

4. The method of claim 3, wherein modeling the temperature of the circuit breaker comprises defining, based on the received sensor data and load data, a predicted temperature response of the circuit breaker over time in response to the ambient conditions and the electrical load.

5. The method of claim 4, further comprising:
determining, from the predicted temperature response, a prediction of whether a predefined temperature alarm for the circuit breaker will be exceeded at a subsequent moment in time; and
generating a notification based on the prediction.

6. The method of claim 4, further comprising defining, from the predicted temperature response, a normality space associated with the circuit breaker, and wherein processing the sensor data and the load data comprises comparing the normality space to a temperature threshold corresponding to a predefined temperature alarm.

7. The method of claim 1, wherein at least one of the one or more sensors is located internally to the circuit breaker.

8. A smart monitoring system for electrical distribution equipment, the electrical distribution equipment including at least one circuit breaker, the circuit breaker comprising a plurality of contacts, the contacts configured to switch between a closed state and an open state, the system comprising:
one or more sensors configured to provide sensor data, the sensor data comprising temperature data associated with the circuit breaker;
a diagnostics processor configured to receive and be responsive to the sensor data and to load data, the load data representative of an electrical load flowing through the electrical distribution equipment; and
a memory coupled to the diagnostics processor, the memory storing processor-executable instructions that, when executed, configure the diagnostics processor for:
processing the sensor data and the load data as inputs to a trained machine learning model to model temperature of the circuit breaker and determine contact resistance between the contacts of the circuit breaker in the closed state based on the modeled temperature.

9. (canceled)

10. The smart monitoring system of claim 8, wherein the sensor data further comprises environmental data associated with ambient conditions of the electrical distribution equipment and wherein the processor-executable instructions, when executed, further configure the diagnostics processor for generating a temperature model of the circuit breaker as a function of the ambient conditions and the electrical load.

11. The smart monitoring system of claim 10, wherein the temperature model of the circuit breaker defines, based on the sensor data and the load data, a predicted temperature response of the circuit breaker over time in response to the ambient conditions and the electrical load.

12. The smart monitoring system of claim 11, wherein the processor-executable instructions, when executed, further configure the diagnostics processor for:
determining, from the predicted temperature response, a prediction of whether a predefined temperature alarm for the circuit breaker will be exceeded at a subsequent moment in time; and
generating a notification based on the prediction.

13. The smart monitoring system of claim 11, wherein the predicted temperature response defines a normality space associated with the circuit breaker, and wherein the processor-executable instructions, when executed, further configure the diagnostics processor for comparing the normality space to a temperature threshold corresponding to a predefined temperature alarm.

14. The smart monitoring system of claim 8, wherein at least one of the one or more sensors is located internally to the circuit breaker.

15. An electrical distribution system comprising:
one or more electric load carrying components configured for supplying power to an electrical load;
at least one circuit breaker electrically connected to the electric load carrying components, the circuit breaker comprising a plurality of contacts, the contacts configured to switch between a closed state and an open state;
one or more sensors configured to provide sensor data, the sensor data comprising temperature data associated with the circuit breaker;
a diagnostics processor configured to receive and be responsive to the sensor data and to load data, the load data representative of the electrical load; and
a memory coupled to the diagnostics processor, the memory storing processor-executable instructions that, when executed, configure the diagnostics processor for:
processing the sensor data and the load data as inputs to a trained machine learning model to model temperature of the circuit breaker and determine contact resistance between the contacts of the circuit breaker in the closed state based on the modeled temperature.

16. The electrical distribution system of claim 15, wherein the sensor data further comprises environmental data associated with ambient conditions of the electric load carrying components.

17. The electrical distribution system of claim 16, wherein the processor-executable instructions, when executed, further configure the diagnostics processor for generating a temperature model of the circuit breaker as a function of the ambient conditions and the electrical load.

18. The electrical distribution system of claim 17, wherein the temperature model of the circuit breaker defines, based on the sensor data and the load data, a predicted temperature response of the circuit breaker over time in response to the ambient conditions and the electrical load.

19. The electrical distribution system of claim 18, wherein the processor-executable instructions, when executed, further configure the diagnostics processor for:
determining, from the predicted temperature response, a prediction of whether a predefined temperature alarm for the circuit breaker will be exceeded at a subsequent moment in time; and
causes a notification to be generated based on the prediction.

20. The electrical distribution system of claim 18, wherein the predicted temperature response defines a normality space associated with the circuit breaker, and wherein the processor-executable instructions, when executed, further configure the diagnostics processor for comparing the normality space to a temperature threshold corresponding to a predefined temperature alarm.

21. The electrical distribution system of claim 15, wherein at least one of the one or more sensors is located internally to the circuit breaker.

22. The electrical distribution system of claim 15, further comprising a gateway of a wireless communications network, wherein the diagnostics processor is configured to receive the sensor data from the sensors wirelessly via the gateway.

23. (canceled)
